(19) United States
(12) Patent Application Publication
(10) Pub. No.: US 2026/0208401 A1
(43) Pub. Date: Jul. 23, 2026

(54) SHAPING METHOD, SHAPING APPARATUS, AND ARTICLE MANUFACTURING METHOD

(71) Applicant: CANON KABUSHIKI KAISHA, Tokyo (JP)

(72) Inventor: Kazuki NAKAGAWA, Tochigi (JP)

(21) Appl. No.: 19/567,520

(22) Filed: Mar. 16, 2026

Related U.S. Application Data
(63) Continuation of application No. PCT/JP2024/031322, filed on Aug. 30, 2024.

(30) Foreign Application Priority Data
Oct. 10, 2023 (JP) 2023-175548

(51) Int. Cl. B29C 35/04; B29C 35/02

(52) U.S. Cl. CPC B29C 35/045; B29C 35/0266; B29C 35/0288; B29C 2035/047

(57) ABSTRACT

The present disclosure provides a shaping method of performing, for each of a plurality of regions on a substrate, a process of curing a composition on the substrate while keeping a mold in contact with the composition and separating the mold from the cured composition, wherein the plurality of regions include a first region that does not include an outer edge portion of the substrate and a second region that includes the outer edge portion, the process includes controlling a gas supplying operation of supplying a gas lower in oxygen concentration than air between the mold and the substrate before bringing the mold into contact with the composition, and the supply amount of the gas in the gas supplying operation in the process for the second region is smaller than that in the process for the first region.

### CROSS-REFERENCE TO RELATED APPLICATIONS

This application is a Continuation of International Patent Application No. PCT/JP2024/031322, filed Aug. 30, 2024, which claims the benefit of Japanese Patent Application No. 2023-175548 filed Oct. 10, 2023, which is hereby incorporated by reference herein in its entirety.

### BACKGROUND

### Field of the Technology

The present disclosure relates to a shaping method, a shaping apparatus, and an article manufacturing method.

### Description of the Related Art

With a growing demand for the miniaturization of semiconductor devices, attention has been paid to imprint techniques in addition to conventional photolithography techniques. An imprint technique is a microfabrication technique of forming the pattern of an imprint material on a substrate by performing the imprint process for shaping an imprint material (composition) on the substrate using a mold. One of the methods of curing an imprint material in the imprint process is, for example, a photo-curing method. In imprint process using the photo-curing method, an imprint material on a substrate is cured by light irradiation while a mold and the imprint material are in contact with each other, and the mold is separated from the cured imprint material, thereby forming the pattern of the imprint material on the substrate. Using such an imprint technique can form a fine structure on the order of several nanometers on the substrate.

In the imprint technique, in a case where a mold is brought into contact with an imprint material on a substrate, air between the mold and the imprint material sometimes remains as air bubbles, thus causing a defect in the pattern of the imprint material formed on the substrate. Such a defect is sometimes called a pattern defect or unfilled defect. Japanese Patent Laid-Open No. 2007-509769 discloses a method of reducing pattern defects by supplying, between the mold and the substrate, a gas exhibiting either or both of solubility and diffusivity with respect to the imprint material.

The imprint process is performed for each of a plurality of shot regions on a substrate. Recently, the imprint process is required to be performed for even a shot region including an outer edge portion of a substrate (a so-called partial shot region) in order to improve the yield of product chips obtained from the substrate. Warpage or a stepped portion is sometimes formed on an outer edge portion of a substrate. An imprint material can be supplied in the form of droplets to such an outer edge portion to prevent a mold from directly coming into contact with the substrate. However, there are cases where contact with (pressing against) the mold of the droplets of the imprint material supplied to the outer edge portion of a substrate on which warpage or a stepped portion is formed is not sufficient and the droplets do not spread on the substrate and partly remain adhering to the mold after the imprint process. If the imprint material adhering to the mold is cured, the material can be a factor that causes a pattern defect in the imprint process for a subsequent shot region.

### SUMMARY

Present disclosure provides a technique advantageous in reducing defects occurring in a composition in the process of shaping the composition on a substrate by using a mold.

According to one aspect of the present disclosure, there is provided a shaping method of performing, for each of a plurality of regions on a substrate, a process of curing a composition on the substrate while keeping a mold in contact with the composition and shaping the composition on the substrate by separating the mold from the cured composition, wherein the plurality of regions include a first region that does not include an outer edge portion of the substrate and a second region that includes the outer edge portion, the composition on the substrate has a property of being inhibited from being cured by oxygen, the process includes controlling a gas supplying operation of supplying a gas lower in oxygen concentration than air between the mold and the substrate before bringing the mold into contact with the composition on the substrate, and the supply amount of the gas in the gas supplying operation in the process for the second region is smaller than the supply amount of the gas in the gas supplying operation in the process for the first region.

Features of the present disclosure will become apparent from the following description of exemplary embodiments with reference to the attached drawings.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a schematic view showing an example of the arrangement of an imprint apparatus.

FIG. 2 is a view showing an example of the layout of a plurality of shot regions on a substrate.

FIG. 3 is a flowchart showing the imprint process according to the first embodiment.

FIG. 4 is a view for explaining the conventional imprint process.

FIG. 5 is a view for explaining the conventional imprint process.

FIG. 6 is a view for explaining the imprint process according to the first embodiment.

FIG. 7 is a view for explaining the imprint process according to the first embodiment.

FIG. 8 is a view for explaining an example in which a residual imprint material in an uncured state is cured as the ambient oxygen concentration decreases.

FIG. 9 is a view showing an example of the layout of a plurality of shot regions on the substrate.

FIG. 10 is a view for explaining the imprint process according to the second embodiment.

FIG. 11 is a view for explaining an article manufacturing method.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

In the specification and the accompanying drawings, directions will be indicated on an XYZ coordinate system in which directions parallel to a surface of a substrate are defined as the X-Y plane, unless otherwise specified. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are θX, θY, and θZ, respectively. Control or driving concerning the X-axis, the Y-axis, and the Z-axis means control or driving concerning a direction parallel to the X-axis, a direction parallel to the Y-axis, and a direction parallel to the Z-axis, respectively. In addition, control or driving concerning the θX-axis, the θY-axis, and the θZ-axis means control or driving concerning a rotation about an axis parallel to the X-axis, a rotation about an axis parallel to the Y-axis, and a rotation about an axis parallel to the Z-axis, respectively. In addition, a position is information that can be specified based on coordinates on the X-, Y-, and Z-axes, and a posture is information that can be specified by values on the θX-, θY-, and θZ-axes.

In addition, a shaping apparatus according to the present invention is an apparatus that performs a shaping process of shaping a composition on a substrate by bringing a mold into contact with the composition on the substrate. Examples of the shaping apparatus are an imprint apparatus and a planarization apparatus. The imprint apparatus is an apparatus that brings a mold including a concave-convex pattern into contact with a composition (imprint material) on a substrate to form (transfer) the pattern in the composition. The shaping process performed by the imprint apparatus is sometimes called an imprint process. The planarization apparatus is an apparatus that planarizes the surface of a composition by bringing a mold having a flat surface into contact with the composition on a substrate. The shaping process performed by the planarization apparatus is sometimes called a planarization process. In the following description, the imprint apparatus will be exemplified as the shaping apparatus, but arrangements/processes of the imprint apparatus can also be applied to the planarization apparatus.

### First Embodiment

The first embodiment according to the present invention will be described. An imprint apparatus is a lithography apparatus that shapes an imprint material (composition) on a substrate by using a mold and can be used for a lithography process that is a manufacturing process for devices such as semiconductor device and magnetic storage media. The imprint apparatus forms the pattern of a cured material, to which the pattern of a mold is transferred, on a substrate by bringing an uncured imprint material supplied onto the substrate into contact with the mold and providing the imprint material with energy for curing. This process is called an imprint process and performed for each of a plurality of shot regions (imprint regions) on a substrate. The present embodiment describes an example using a photo-curing method of curing an imprint material on a substrate by irradiating the material with light (ultraviolet light).

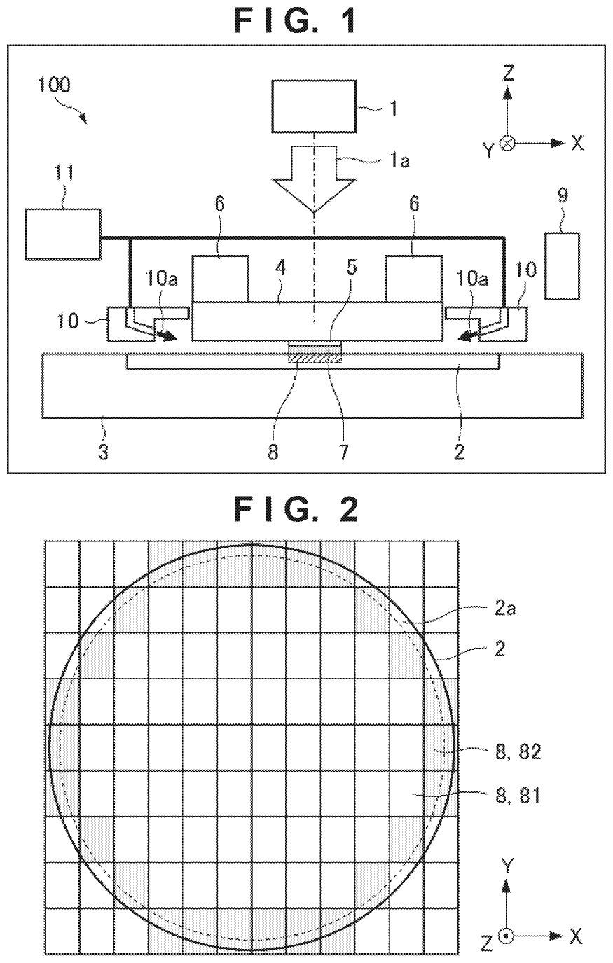

FIG. 1 is a schematic view showing an example of the arrangement of an imprint apparatus 100 according to the present embodiment. The imprint apparatus 100 according to the present embodiment includes a light irradiator 1, a substrate stage 3, a mold holder 6, a liquid supplier 9, a gas supplier 10, and a controller 11. The controller 11 is implemented by a computer (information processor) including a processor such as a Central Processing Unit (CPU) and a storage unit such as a memory. The controller 11 is connected to each unit of the imprint apparatus 100 via a line and controls each unit of the imprint apparatus 100 (controls the imprint process).

The light irradiator 1 (curing unit) cures an imprint material 7 on a substrate 2 (a shot region) by irradiating the imprint material 7 with light 1a (for example, ultraviolet light) while a mold 4 is in contact with the imprint material 7 in the imprint process. The light irradiator 1 can include, for example, a light source and an optical element for adjusting light emitted from the light source into light suitable for the imprint process.

The mold holder 6 is a mechanism that moves the mold 4 in the Z direction while holding the mold 4. More specifically, the mold holder 6 can include a mold chuck that holds the mold 4 and a mold drive mechanism that drives the mold 4 (mold chuck). For example, the mold holder 6 can hold the mold 4 by attracting a peripheral region of the surface of the mold 4 irradiated with the light 1a using a vacuum suction force or electrostatic force.

The mold holder 6 can drive the mold 4 in each axial direction so as to perform a pressing operation (mold-pressing operation) with respect to the mold 4 and the imprint material 7 on the substrate 2 and a separating operation (mold-separating operation) of separating the mold 4 from the cured imprint material 7 on the substrate 2. The mold holder 6 may be constituted by a plurality of drive systems such as a coarse drive system and a fine drive system to meet the requirement for accurate positioning of the mold 4. In addition, the mold holder 6 may have an arrangement including a position adjustment function for adjusting the position of the mold 4 not only in the Z direction but also in the X direction, the Y direction, and rotating directions about the respective axes (θX, θY, and θZ directions) or a tilt function for correcting the tilt of the mold 4. Note that a mold-pressing operation and a mold-separating operation in the imprint process may be implemented by driving the mold 4 in the Z direction using the mold holder 6 or by driving the substrate 2 in the Z direction using the substrate stage 3 (to be described later). Alternatively, a mold-pressing operation and a mold-separating operation may be implemented by relatively driving the mold 4 and the substrate 2 in the Z direction using both the mold holder 6 and the substrate stage 3.

The mold 4 held by the mold holder 6 generally has a rectangular outer peripheral shape and is manufactured by using a material that can transmit light 1a (ultraviolet light), such as silica glass. A partial region of the surface of the mold 4 which faces the substrate 2 is provided with a mesa portion 5 formed into a mesa shape having a level difference of about several tens of nm. The surface of the mesa portion 5 on the substrate 2 side functions as a shaping surface (contact surface) which comes into contact with the imprint material 7 on the substrate 2 to shape the imprint material 7. The shaping surface of the mold 4 used in the imprint apparatus 100 is formed as a pattern surface on which a concave-convex pattern to be transferred to the imprint material 7 on the substrate 2, such as a circuit pattern, is formed. In the following description, the mesa portion 5 on which a concave-convex pattern is formed will sometimes be referred to as the “pattern portion 5”. Note that the shaping surface of the mold 4 used in a planarization apparatus is formed as a planarization surface on which no concave-convex pattern is formed.

The substrate stage 3 is a mechanism that moves the substrate 2 in the X and Y directions while holding the substrate 2. More specifically, the substrate stage 3 includes a substrate chuck that holds the substrate 2 and a substrate drive mechanism that drives the substrate 2 (substrate chuck) in each axial direction. The substrate stage 3 can be used to align the mold 4 (the pattern portion 5) with the substrate 2 (a shot region 8) when pressing the mold 4 against the imprint material 7 on the substrate 2 (the shot region 8). The substrate stage 3 may be constituted by a plurality of drive systems such as a coarse drive system and a fine drive system with respect to each of the X and Y directions. The substrate stage 3 may be an arrangement including a position adjusting function for adjusting the position of the substrate 2 in not only the X and Y directions but also in the Z direction and the rotating directions about the respective axes (the θX, θY, and θZ directions) or a tilt function for correcting the tilt of the substrate 2.

As a material for the substrate 2, for example, glass, ceramic, metal, semiconductor, resin, or the like is used. The surface of the substrate 2 may be provided with a member made of a material different from the substrate 2 as needed. For example, the substrate 2 can be a silicon wafer, compound semiconductor wafer, or silica glass. In the present embodiment, the substrate 2 is, for example, a single-crystal silicon substrate or Silicon on Insulator (SOI) substrate. The imprint material 7 on which a pattern is formed by the mold 4 (the pattern portion 5) is supplied (coated) on the processing surface of the substrate 2.

The liquid supplier 9 supplies the imprint material 7 in the form of droplets onto the substrate 2. The liquid supplier 9 may be understood as a liquid discharge head that discharges (sprays) the imprint material 7 in the form of droplets toward the substrate 2. For example, the liquid supplier 9 discharges the imprint material 7 in the form of droplets while the substrate stage 3 moves the substrate 2 relatively to the liquid supplier 9 in the X and Y directions below the liquid supplier 9. This makes it possible to supply the imprint material 7 in the form of droplets onto the substrate 2 (the shot region 8).

As the imprint material 7 supplied onto the substrate 2, a curable composition (to be sometimes referred to as a resin in an uncured state) that is cured upon reception of curing energy is used. A curable composition is a composition cured by light irradiation or heating. Among these compositions, the curable composition that is cured by light irradiation may contain at least a polymerizable compound and a photopolymerization initiator and may further contain a non-polymerizable compound or solvent as needed. A non-polymerizable compound is at least one type of material selected from the group consisting of a sensitizer, a hydrogen donor, an internal mold release agent, a surfactant, an antioxidant, a polymer component, and the like. The viscosity (at 25° C.) of a viscoelastic material is, for example, 1 mPa·s or more and 100 mPa·s or less. In addition, the imprint material 7 used in the present embodiment has a property (characteristic) of being inhibited by oxygen from being cured.

The gas supplier 10 supplies a gas 10a to the space between the mold 4 and the substrate 2 so as to replace the space with the gas 10a. In the imprint apparatus 100, when the mold 4 comes into contact with the imprint material 7 on the substrate 2 in an air atmosphere, air between the mold 4 and the imprint material 7 can mix (remain) as air bubbles in the imprint material 7. In this case, a portion where air bubbles are generated is not filled with the imprint material 7. If the imprint material 7 is cured in this state, a defect can occur in the pattern of the imprint material 7 formed on the substrate 2. Such a defect is sometimes called a pattern defect or unfilled defect. For this reason, in the imprint apparatus 100 according to the present embodiment, the gas supplier 10 supplies the gas 10a to between the mold 4 and the substrate 2 before the mold 4 is brought into contact with the imprint material 7 on the substrate 2 in the imprint process. The gas 10a is a gas having a lower oxygen concentration than air and can be, for example, a permeable gas that easily permeates through the mold 4 or the imprint material 7 at the time of a mold-pressing operation. As a permeable gas, a rare gas such as helium (He) can be used. In this case, the gas supplier 10 is arranged around the mold 4 so as to surround the mold 4 held by the mold holder 6. The controller 11 controls the supply amount of the gas 10a supplied between the mold 4 and the substrate 2 by the gas supplier 10.

As shown in FIG. 2, the imprint apparatus 100 having the above arrangement sequentially executes the imprint process for each of the plurality of shot regions 8 on the substrate 2. In the imprint process, after the mold 4 and the substrate 2 are positioned in a predetermined positional relationship, the mold holder 6 moves the mold 4 in the −Z direction to press (make contact) the pattern portion 5 of the mold 4 against the imprint material 7 on the substrate 2 (the shot region 8). After the imprint material 7 is cured while the pattern portion 5 of the mold 4 is in contact with the imprint material 7 on the substrate 2, the mold 4 is separated from the cured imprint material 7 on the substrate 2. This makes it possible to form, on the substrate 2, the pattern formed of the cured material of the imprint material 7.

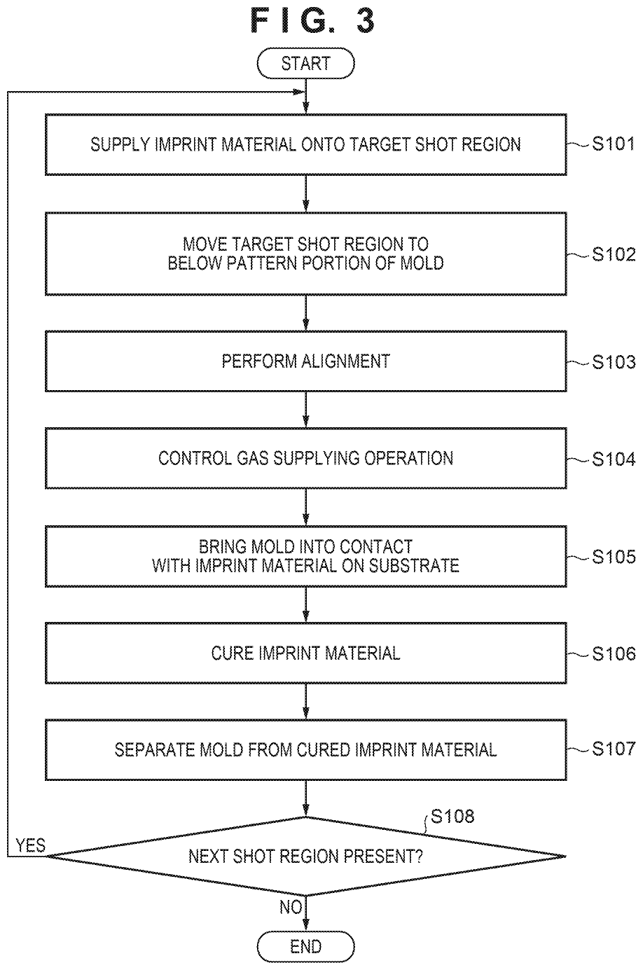

The imprint process according to the present embodiment will be described next. FIG. 3 is a flowchart showing the imprint process according to the present embodiment. The flowchart of FIG. 3 can be executed by the controller 11.

In step S101, the controller 11 supplies the imprint material 7 in the form of droplets onto the shot region 8 (to be sometimes referred to as the target shot region 8 hereinafter), of the plurality of shot regions 8 on the substrate 2, for which the imprint process is to be performed. For example, the controller 11 causes the liquid supplier 9 to discharge the imprint material 7 in the form of droplets while causing the substrate stage 3 to move the substrate 2 in the X and Y directions below the liquid supplier 9. This makes it possible to supply the imprint material 7 in the form of droplets onto the target shot region 8 on the substrate 2.

In step S102, the controller 11 causes the substrate stage 3 to move the substrate 2 so as to place the target shot region 8 of the substrate 2 below the pattern portion 5 of the mold 4. In step S103, the controller 11 aligns the pattern portion 5 of the mold 4 with the target shot region 8 of the substrate 2 by causing the substrate stage 3 to adjust the position of the substrate 2 in the X and Y directions. This alignment can be performed based on the result of measuring the relative position between an alignment mark on the pattern portion 5 and an alignment mark on the target shot region 8 by using an alignment measurement unit (not shown).

In step S104, the controller 11 controls the gas supplying operation of supplying the gas 10a to between the mold 4 and the substrate 2 by using the gas supplier 10. The gas 10a is a gas having a lower oxygen concentration than air. For example, helium can be used as the gas 10a. In the present embodiment, the gas supplying operation in step S104 is performed after step S102. However, limitation is not made thereto. In the imprint apparatus 100, since the interval between the mold 4 and the substrate 2 is very small, it is sometimes difficult to supply the gas 10a to between the mold 4 and the substrate 2 by using the gas supplier 10 while the substrate 2 is placed below the mold 4. For this reason, the gas supplying operation in step S104 may be performed before step S102 of moving the substrate 2 to below the mold 4 or may be performed concurrently with step S102. For example, a gas supplying operation may be performed by causing the gas supplier 10 to supply the gas 10a to below the mold 4 before the substrate 2 is placed below the mold 4 and then moving the substrate 2 to below the mold 4 while the below the mold 4 is filled with the gas 10a.

In step S105, the controller 11 brings the mold 4 into contact with the imprint material 7 on the substrate 2 by causing the mold holder 6 to move the mold 4 in the −Z direction. In step S106, the controller 11 causes the light irradiator 1 to cure the imprint material 7 on the substrate 2 by irradiating the imprint material 7 with the light 1a while the mold 4 is in contact with the imprint material 7. In step S107, the controller 11 separates the mold 4 from the cured imprint material 7 on the substrate 2 by causing the mold holder 6 to move the mold 4 in the +Z direction.

In step S108, the controller 11 determines whether there is the shot region 8 for which the imprint process has not been performed, that is, the shot region for which the imprint process should be performed next (to be sometimes referred to as a next shot region hereinafter) on the substrate 2. If there is a next shot region, the process advances to step S101, in which the controller 11 performs the imprint process for the next shot region as a target shot region. If there is no next shot region, the processing is terminated.

As shown in FIG. 2, the plurality of shot regions 8 on the substrate 2 can be roughly classified into full shot regions 81 and partial shot regions 82. The full shot region 81 is the shot region 8 (the first region) that is placed in the central area of the substrate 2 and does not include an outer edge portion 2a of the substrate 2. The overall pattern provided on the pattern portion 5 of the mold 4 is transferred to the full shot regions 81. The partial shot region 82 is the shot region 8 (the second region) that is placed in a peripheral area of the substrate 2 and includes the outer edge portion 2a of the substrate 2. Only part of the pattern provided on the pattern portion 5 of the mold 4 is transferred to the partial shot regions 82. Note that the full shot region 81 is sometimes called a complete shot region or central shot region. The partial shot region 82 is sometimes called a clipped shot region or peripheral shot region.

Recently, in order to improve the yield of product chips obtained from the substrate 2, the imprint process is required to be performed even for the partial shot region 82 including the outer edge portion 2a of the substrate 2. In the imprint process for the partial shot region 82, in order to prevent the mold 4 and the substrate 2 from coming into direct contact with each other, droplets of the imprint material 7 can also be supplied onto the outer edge portion 2a of the substrate 2. However, warpage (deflection) may occur in the outer edge portion 2a of the substrate 2 due to the shape or suction pressure of the substrate stage 3 (substrate chuck) or may have a stepped portion upon undergoing a preprocess (for example, a patterning process for forming an underlying pattern). In addition, an outer edge portion of the substrate 2 has sometimes undergone a chamfering process (beveling process). Contact with (pressing against) the mold 4 of the droplets of the imprint material 7 which are supplied to such an outer edge portion is insufficient and hence the droplets do not spread on the substrate 2. Consequently, after the imprint process, some of the droplets sometimes remain adhering to the mold 4. The cured imprint material 7 adhering to the mold 4 can be a factor that causes a pattern defect in the imprint process for a succeeding shot region.

The controller 11 according to the present embodiment controls a gas supplying operation so as to prevent the imprint material 7 adhering to the mold 4 in the imprint process for the partial shot region 82 from being cured by using the property of the imprint material 7 in which curing is inhibited by oxygen. More specifically, the controller 11 controls the gas supplying operation in the imprint process for the partial shot region 82 such that the supply amount of the gas 10a is smaller than that in the gas supplying operation in the imprint process for the full shot region 81. That is, the controller 11 controls the gas supplying operation such that the oxygen concentration around the partial shot region 82 at the time of curing the imprint material 7 on the partial shot region 82 is higher than that around the full shot region 81 at the time of curing the imprint material 7 on the full shot region 81.

This makes it possible to avoid some of the droplets of the imprint material 7 supplied to the outer edge portion 2a of the substrate 2 adhering in a cured state to the pattern portion 5 of the mold 4 in the imprint process for the partial shot region 82. That is, even if the imprint material 7 adheres to the pattern portion 5 of the mold 4 due to the imprint process for the partial shot region 82, it is possible to make the imprint material 7 remain in an uncured state on the pattern portion 5 of the mold 4. The imprint material 7 remaining in the uncured state on the pattern portion 5 of the mold 4 is integrated (mixed, merged, or fused) with the imprint material 7 on the shot region 8 (the third region) for which the imprint process is performed next. This makes it possible to remove the imprint material 7 remaining on the pattern portion 5 of the mold 4 and reduce the occurrence of pattern defects in the imprint process for the succeeding shot region 8.

The imprint process according to the present embodiment will be described in comparison with the conventional imprint process. Note that the imprint material 7 remaining and adhering to the pattern portion 5 of the mold 4 is sometimes written as a “residual imprint material 7′” hereinafter.

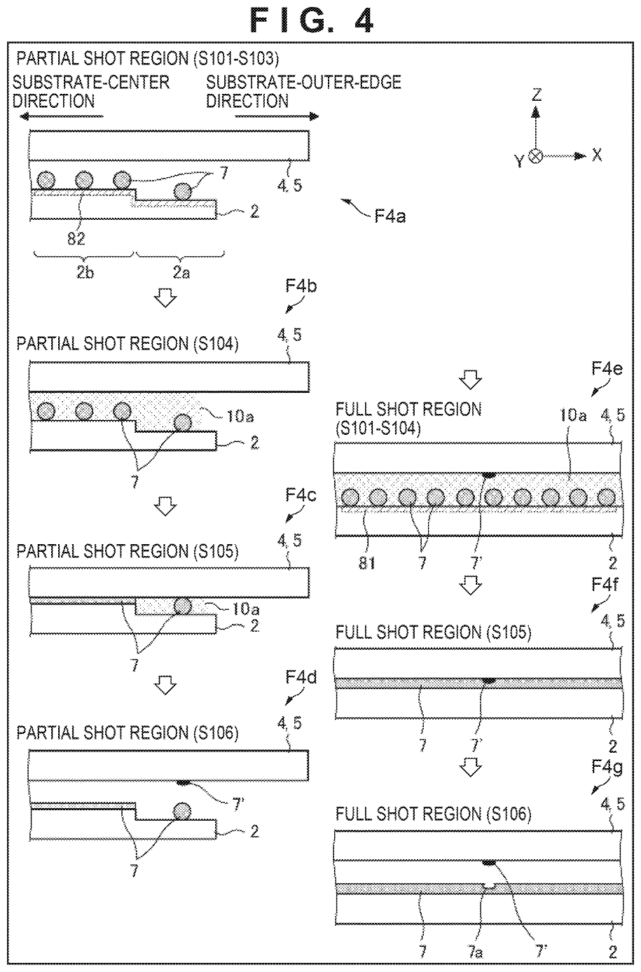

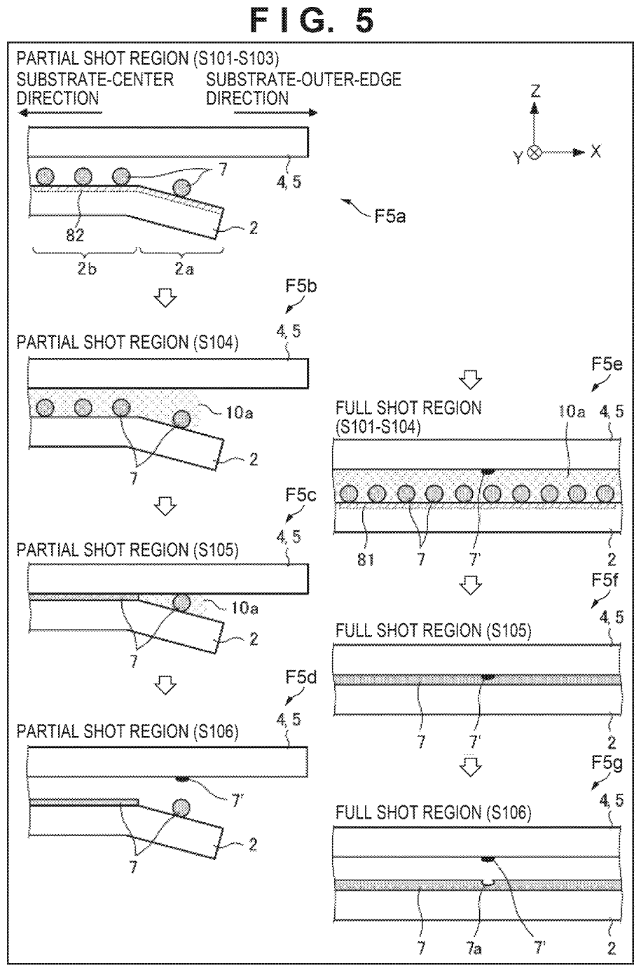

The conventional imprint process will be described first with reference to FIGS. 4 and 5. FIGS. 4 and 5 are views for explaining the conventional imprint process. FIG. 4 shows an example in which warpage has occurred in the outer edge portion 2a of the substrate 2. FIG. 5 shows an example in which a stepped portion is formed on the outer edge portion 2a of the substrate 2. In addition, FIGS. 4 and 5 show steps corresponding to the flowchart of FIG. 3.

F4a to F4d in FIG. 4 and F5a to F5d in FIG. 5 each indicate a conventional example of the imprint process for the partial shot region 82. As described above, the partial shot region 82 includes the outer edge portion 2a of the substrate 2 where warpage occurs or a stepped portion is formed.

F4a in FIG. 4 and F5a in FIG. 5 each show a state after alignment between the pattern portion 5 of the mold 4 and the partial shot region 82 of the substrate 2 through steps S101 to S103. The imprint material 7 has been supplied in the form of droplets onto the partial shot region 82. In addition, as described above, droplets of the imprint material 7 have also been supplied onto the outer edge portion 2a of the substrate 2 to prevent the mold 4 from coming into direct contact with the substrate 2.

F4b in FIG. 4 and F5b in FIG. 5 each indicate a state in which a gas supplying operation is controlled for the partial shot region 82 through step S104. Conventionally, even in the imprint process for the partial shot region 82, a gas supplying operation similar to that in the imprint process for the full shot region 81 is performed. For example, conventionally, a gas supplying operation in the imprint process for the partial shot region 82 is controlled to set the same supply amount of the gas 10a as that in a gas supplying operation in the imprint process for the full shot region 81. That is, a gas supplying operation is controlled such that the oxygen concentration around the partial shot region 82 at the time of curing the imprint material 7 on the partial shot region 82 is the same as the oxygen concentration around the full shot region 81 at the time of curing the imprint material 7 on the full shot region 81.

F4c in FIG. 4 and F5c in FIG. 5 each indicate a state in which the mold 4 is in contact with the imprint material 7 on the partial shot region 82 through step S105. At this time, the droplets of the imprint material 7 supplied onto the portion 2b other than the outer edge portion 2a of the partial shot region 82 are spread and filled between the mold 4 and the substrate 2 by the mold 4 (the pattern portion 5). In contrast, the droplets of the imprint material 7 supplied onto the outer edge portion 2a are not sufficiently spread by the mold 4, and the upper portions of the droplets are in slight contact with the mold 4. In this state, the imprint material 7 is cured by being irradiated with light 1a in step S106.

F4d in FIG. 4 and F5d in FIG. 5 each show a state in which the mold 4 is separated from the imprint material 7 arranged on the partial shot region 82 and cured through step S106. In this case, since the droplets of the imprint material 7 on the outer edge portion 2a of the substrate 2 are not sufficiently spread on the substrate 2, the adhesion to the substrate 2 is insufficient. For this reason, some of the droplets of the imprint material 7 on the outer edge portion 2a adhere to the pattern portion 5 of the mold 4 and remain as the residual imprint material 7′ on the pattern portion 5.

Conventionally, the residual imprint material 7′ has been cured (in a cured state) by being irradiated with the light 1a. For this reason, the next imprint process is performed while the cured residual imprint material 7′ remains on the pattern portion 5 of the mold 4. F4e to F4g in FIG. 4 and F5e to F5g in FIG. 5 each show a conventional example of the next imprint process. The following exemplifies a case where the next imprint process is the imprint process for the full shot region 81. However, the same applies to a case where the next imprint process is the imprint process for another partial shot region 82.

F4e in FIG. 4 and F5e in FIG. 5 each indicate a state in which a gas supplying operation for the full shot region 81 is controlled through steps S101 to S104. As described above, the gas supplying operation for the full shot region 81 is performed to prevent the occurrence of a pattern defect (unfilled defect) caused by the mixing of air in the imprint material 7 in the form of air bubbles. As described above, the gas 10a supplied between the mold 4 and the substrate 2 in the gas supplying operation is a gas with an oxygen concentration lower than that of air, for example, which can be a permeable gas such as helium, which easily permeates the mold 4 or the imprint material 7 in a mold pressing operation.

F4f in FIG. 4 and F5f in FIG. 5 each indicate a state in which the mold 4 is in contact with the imprint material 7 on the full shot region 81 through step S105. F4g in FIG. 4 and F5g in FIG. 5 each indicate a state in which the mold 4 is separated from the imprint material 7 arranged on the full shot region 81 and cured through step S106. Conventionally, the cured residual imprint material 7′ adhering to the mold 4 (the pattern portion 5) comes into contact with the imprint material 7 spread on the full shot region 81 by the mold 4. The cured residual imprint material 7′ remains on the pattern portion 5 even after the mold 4 is separated from the imprint material 7 cured on the full shot region 81. As a result, a pattern defect (unfilled defect) can occur in a portion 7a with which the cured residual imprint material 7′ of the cured imprint material 7 on the full shot region 81 is in contact.

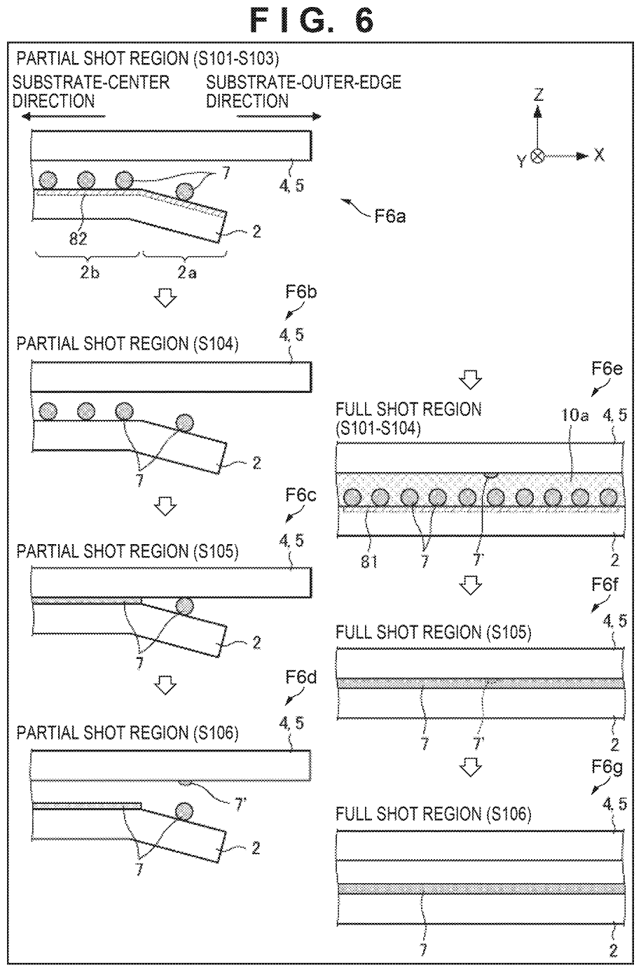

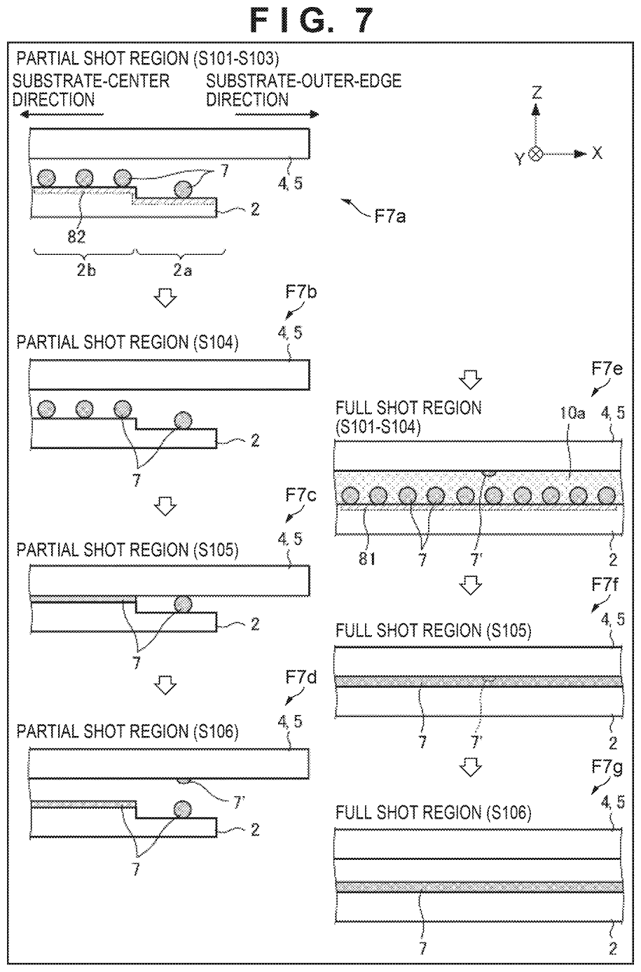

The imprint process according to the present embodiment will be described next with reference to FIGS. 6 and 7. FIGS. 6 and 7 are views for explaining the imprint process according to the present embodiment. FIG. 6 shows an example in which warpage has occurred in the outer edge portion 2a of the substrate 2. FIG. 7 shows an example in which a stepped portion is formed on the outer edge portion 2a of the substrate 2. FIGS. 6 and 7 show steps corresponding to the flowchart of FIG. 3.

F6a to F6d in FIG. 6 and F7a to F7d in FIG. 7 each indicate an example of the imprint process for the partial shot region 82 according to the present embodiment. As described above, the partial shot region 82 includes the outer edge portion 2a of the substrate 2 where deflection or a stepped portion is generated.

F6a in FIG. 6 and F7a in FIG. 7 each indicate a state after alignment between the pattern portion 5 of the mold 4 and the partial shot region 82 of the substrate 2 through steps S101 to S103. The imprint material 7 has been supplied in the form of droplets onto the partial shot region 82. In addition, as described above, droplets of the imprint material 7 have also been supplied onto the outer edge portion 2a of the substrate 2 to prevent the mold 4 from coming into direct contact with the substrate 2.

F6b in FIG. 6 and F7b in FIG. 7 each show a state in which a gas supplying operation for the partial shot region 82 is controlled through step S104. In the present embodiment, a gas supplying operation in the imprint process for the partial shot region 82 is controlled such that the supply amount of the gas 10a between the mold 4 and the substrate 2 is smaller than that in a gas supplying operation in the imprint process for the full shot region 81. That is, a gas supplying operation is controlled such that the oxygen concentration around the partial shot region 82 at the time of curing the imprint material 7 on the partial shot region 82 is higher than the oxygen concentration around the full shot region 81 at the time of curing the imprint material 7 on the full shot region 81. More specifically, the supply amount of the gas 10a in the imprint process for the partial shot region 82 is controlled such that in the imprint process for the partial shot region 82, a residual imprint material 7′ adhering to the mold 4 through the imprint process remains in an uncured state by being prevented from being cured by oxygen around the residual imprint material 7′. In a gas supplying operation in the imprint process for the partial shot region 82, the gas 10a need not be supplied between the mold 4 and the substrate 2.

F6c in FIG. 6 and F7c in FIG. 7 each indicate a state in which the mold 4 is in contact with the imprint material 7 on the partial shot region 82 through step S105. In the present embodiment, as described above, the supply amount of the gas 10a supplied between the mold 4 and the substrate 2 in a gas supplying operation in the imprint process for the partial shot region 82 is smaller than that in a gas supplying operation in the imprint process for the full shot region 81. Alternatively, the gas 10a is not supplied between the mold 4 and the substrate 2. For this reason, the time required until the convex portion of the pattern portion 5 of the mold 4 is filled with the imprint material 7 in the imprint process for the partial shot region 82 is longer than that in the imprint process for the full shot region 81. Accordingly, the time (waiting time) of waiting for the concave portion of the pattern portion 5 to be filled with the imprint material 7 in the imprint process for the partial shot region 82 is preferably longer than that in the imprint process for the full shot region 81. The waiting time may be understood as the time from bringing the mold 4 into contact with the imprint material 7 on the substrate 2 to starting to cure the imprint material.

F6d in FIG. 6 and F7d in FIG. 7 each indicate a state in which the mold 4 is separated from the imprint material 7 arranged on the partial shot region 82 and cured through step S106. In this case, some of the droplets of the imprint material 7 on the outer edge portion 2a adhere to the pattern portion 5 of the mold 4 and remain as the residual imprint material 7′ on the pattern portion 5.

In this case, as described above, the imprint material 7 contains at least a polymerizable compound and a photopolymerization initiator. The imprint material 7 is cured when the radicals generated from the photopolymerization initiator irradiated with the light 1a (ultraviolet light) cause a polymerization reaction of the polymerizable compound. Oxygen reacts with the radicals generated from the photopolymerization initiator irradiated with the light 1a (ultraviolet light) to eliminate the radicals. This inhibits the polymerization reaction of the polymerizable compound. This means that oxygen inhibits curing of the imprint material 7.

In the present embodiment, since the supply amount of a gas 10a in a gas supplying operation in the imprint process for the partial shot region 82 is smaller than that in the imprint process for the full shot region 81, the concentration of the gas 10a between the mold 4 and the substrate 2 is low. That is, the oxygen concentration between the mold 4 and the substrate 2 in the imprint process for the partial shot region 82 is higher than that in the imprint process for the full shot region 81.

The droplets of the imprint material 7 supplied to the portion 2b of the partial shot region 82 other than the outer edge portion 2a are spread by the mold 4 (the pattern portion 5) and filled in between the pattern portion 5 and the partial shot region 82. At this time, since oxygen is pushed out from between the pattern portion 5 and the imprint material 7 on the portion 2b, the imprint material 7 on the portion 2b can be cured by irradiation with light 1a (ultraviolet light). On the other hand, since an atmosphere containing oxygen is present around the droplets of the imprint material 7 supplied to the outer edge portion 2a, the droplets are prevented (suppressed) from being cured by oxygen. In a case where the gas 10a is not supplied between the mold 4 and the substrate 2 in a gas supplying operation in step S104, the oxygen concentration around the droplets of the imprint material 7 supplied to the outer edge portion 2a increases, and the effect of preventing (suppressing) the droplets of the imprint material 7 from being cured is high.

In the present embodiment, as described above, the residual imprint material 7′ adhering to the mold 4 (the pattern portion 5) remains in an uncured state, and the next imprint process is performed while the residual imprint material 7′ in an uncured state keeps adhering to the mold 4. The residual imprint material 7′ in the uncured state which is adhering to the mold 4 is vaporized and eliminated with the lapse of time if the amount of the residual imprint material 7′ is small. Accordingly, there is little possibility that a pattern defect will be formed in the next imprint process. Even if the next imprint process is performed before the residual imprint material 7′ is eliminated, the uncured residual imprint material 7′ adhering to the mold 4 is integrated (mixed, merged, or fused) with the imprint material 7 supplied onto the substrate 2 in the next imprint process. This makes it possible to perform the next imprint process without waiting for the elimination of the uncured residual imprint material 7′.

F6e to F6g in FIG. 6 and F7e to F7g in FIG. 7 each indicate an example of the next imprint process in the present embodiment. The following exemplifies a case where the next imprint process is the imprint process for the full shot region 81. However, the same applies to a case where the next imprint process is the imprint process for another partial shot region 82.

F6e in FIG. 6 and F7e in FIG. 7 each indicate a state in which a gas supplying operation for the full shot region 81 is controlled through steps S101 to S104. As described above, in the gas supplying operation for the full shot region 81, the gas 10a is supplied between the mold 4 and the substrate 2 so as to prevent the occurrence of a pattern defect (unfilled defect) caused by the mixing of air in the imprint material 7 in the form of air bubbles. That is, the gas supplying operation for the full shot region 81 is controlled such that the supply amount of the gas 10a is larger than that in the gas supplying operation for the partial shot region 82.

F6f in FIG. 6 and F7f in FIG. 7 each indicate a state in which the mold 4 is in contact with the imprint material 7 on the full shot region 81 through step S105. F6g in FIG. 6 and F7g in FIG. 7 each show a state in which the mold 4 is separated from the cured imprint material 7 on the full shot region 81 through step S106. In the present embodiment, the residual imprint material 7′ adhering to the pattern portion 5 of the mold 4 is in the uncured state. Accordingly, when the mold 4 (the pattern portion 5) comes into contact with the imprint material 7 on the full shot region 81, the residual imprint material 7′ is integrated with the imprint material 7 on the full shot region 81. This can reduce the occurrence of pattern defects (unfilled defects) caused by the residual imprint material 7′ in the cured imprint material 7 on the full shot region 81.

As described above, in the present embodiment, a gas supplying operation in the imprint process for the partial shot region 82 is controlled such that the supply amount of the gas 10a is smaller than that in a gas supplying operation in the imprint process for the full shot region 81. This makes it possible to keep the residual imprint material 7′ adhering to the pattern portion 5 of the mold 4 in the imprint process for the partial shot region 82 in the uncured state. As a result, it is possible to reduce the occurrence of pattern defects due to the residual imprint material 7′ in succeeding the imprint process. That is, it is possible to reduce defects occurring in the imprint material 7 on the substrate 2 in the imprint process.

### Second Embodiment

The second embodiment according to the present invention will be described. The present embodiment basically follows the first embodiment and can comply with the first embodiment except for the matters described below.

The curing reaction of a residual imprint material 7′ in an uncured state which adheres to a mold 4 (a pattern portion 5) can progress with a reduction in ambient oxygen concentration. For example, an imprint material 7 has the property of being cured upon progression of polymerization reaction with a reduction in ambient oxygen concentration when a photopolymerization initiator starts reacting once irradiated with light 1a (ultraviolet light). Accordingly, the residual imprint material 7′ is sometimes cured by a reduction in ambient oxygen concentration even if the residual imprint material 7′ is in an uncured state immediately after the imprint process of a partial shot region 82.

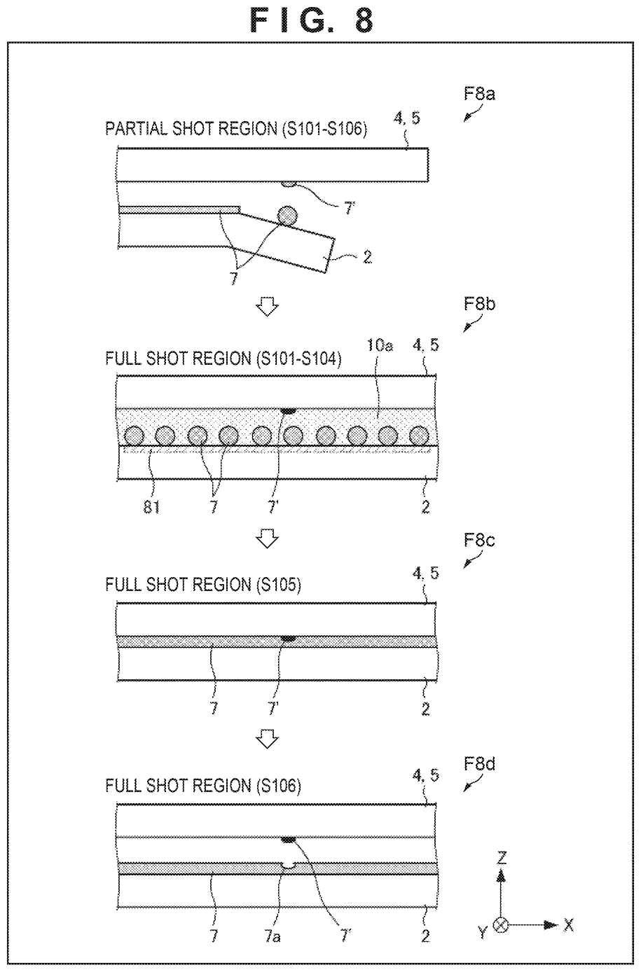

FIG. 8 shows an example in which the residual imprint material 7′ in an uncured state immediately after the end of the imprint process for the partial shot region 82 is cured by a reduction in ambient oxygen concentration. F8a in FIG. 8 indicates a state in which the mold 4 is separated from the cured imprint material 7 on the partial shot region 82 through steps S101 to S106. At this time, some of the droplets of the imprint material 7 on an outer edge portion 2a adhere to the mold 4 (the pattern portion 5) and remain as the residual imprint material 7′ in an uncured state on the mold 4.

F8b to F8d in FIG. 8 each indicate an example in which the next imprint process is performed for a full shot region 81. F8b in FIG. 8 indicates a state in which a gas supplying operation for the full shot region 81 is controlled through steps S101 to S104. F8c in FIG. 8 indicates a state in which the mold 4 is in contact with the imprint material 7 on the full shot region 81 through step S105. F8d in FIG. 8 indicates a state in which the mold 4 is separated from the cured imprint material 7 on the full shot region 81 through step S106.

As described above, in a gas supplying operation for the full shot region 81, a gas 10a is supplied between the mold 4 and a substrate 2 to prevent the occurrence of a pattern defect (unfilled defect) caused by the mixing of air in the imprint material 7 in the form of air bubbles. That is, the gas supplying operation for the full shot region 81 is controlled such that the supply amount of the gas 10a is larger than that in the gas supplying operation for the partial shot region 82. At this time, since the oxygen concentration around the residual imprint material 7′ in an uncured state which adheres to the pattern portion 5 of the mold 4 decreases, the curing reaction of the residual imprint material 7′ progresses. This can cure the residual imprint material 7′. The residual imprint material 7′ in a cured state remains on the pattern portion 5 even after the mold 4 is separated from the cured imprint material 7 on the full shot region 81. This can cause a pattern defect (unfilled defect) in a portion 7a with which the residual imprint material 7′ in a cured state, of the cured imprint material 7 on the full shot region 81, is in contact.

Accordingly, in the present embodiment, the imprint process (to be sometimes referred to as a specific imprint process hereinafter) for removing the residual imprint material 7′ adhering to the pattern portion 5 of the mold 4 is performed subsequent to the imprint process for the partial shot region 82. The supply amount of the gas 10a in a gas supplying operation in the specific imprint process is controlled to become smaller than the normal supply amount of the gas 10a in a gas supplying operation in the imprint process for the full shot region 81. In a gas supplying operation in the specific imprint process, the gas 10a may not be supplied between the mold 4 and the substrate 2.

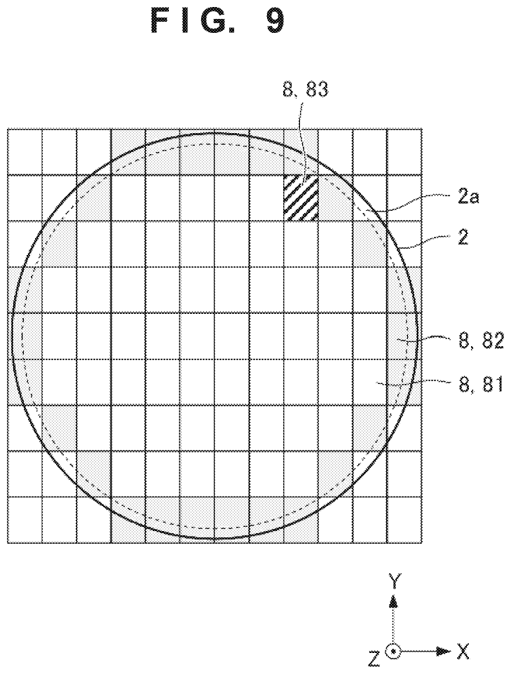

As shown in FIG. 9, the specific imprint process is performed for a full shot region 83 (third region), of the plurality of shot regions 8 of the substrate 2, which is arranged in the central area of the substrate 2 and does not include the outer edge portion 2a of the substrate 2. In this case, the full shot region 83 for which the specific imprint process is performed may be the shot region 8, of the plurality of shot regions 8 of the substrate 2, for which the imprint process is performed last. Alternatively, after the specific imprint process is performed for the full shot region 83, the imprint process may be performed for another full shot region 81.

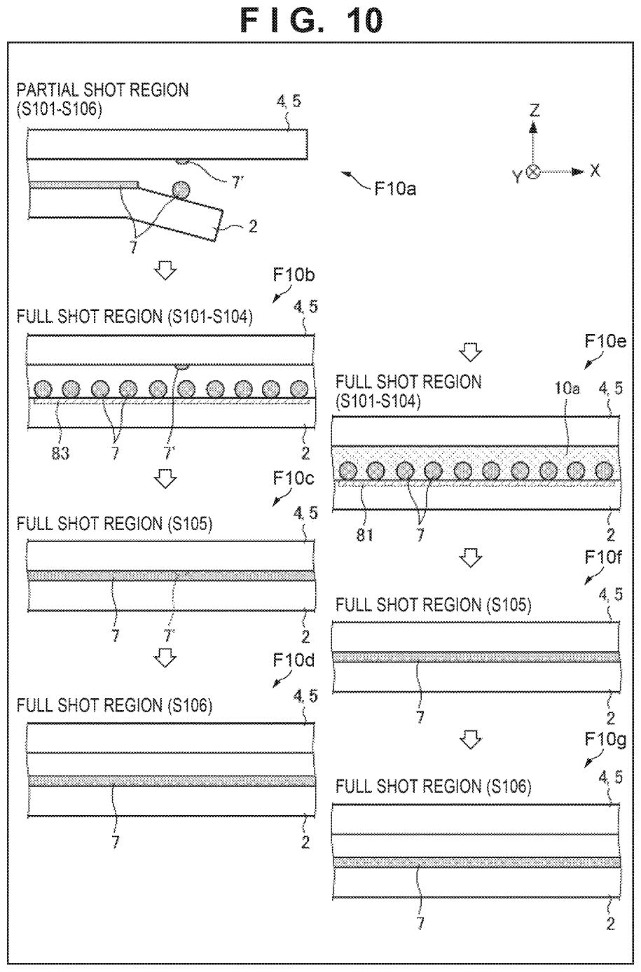

The imprint process according to the present embodiment will be described next with reference to FIG. 10. The following is a description of an example in which after the specific imprint process is performed for the full shot region 83, the imprint process is performed for another full shot region 81.

F10a in FIG. 10 indicates a state in which the mold 4 is separated from the cured imprint material 7 on the partial shot region 82 through steps S101 to S106. In this case, some of the droplets of the imprint material 7 on the outer edge portion 2a adhere to the mold 4 (the pattern portion 5) and remain as the residual imprint material 7′ in an uncured state on the mold 4.

F10b to F10d in FIG. 10 each indicate an example in which the specific imprint process is performed for the full shot region 83. F10b in FIG. 10 indicates a state in which a gas supplying operation for the full shot region 83 is controlled through steps S101 to S104 in the specific imprint process. In the present embodiment, the supply amount of the gas 10a in a gas supplying operation in the specific imprint process is controlled to be smaller than that in a gas supplying operation in the imprint process for another full shot region 81. That is, the oxygen concentration around the full shot region 83 at the time of curing the imprint material 7 on the full shot region 83 in the specific imprint process is higher than that around the full shot region 81 at the time of curing the imprint material 7 on the full shot region 81. More specifically, in the specific imprint process, the supply amount of the gas 10a is controlled such that the residual imprint material 7′ adhering to the mold 4 is inhibited from being cured by ambient oxygen so as to remain in an uncured state. In a gas supplying operation in the specific imprint process, the gas 10a may not be supplied between the mold 4 and the substrate 2.

F10c in FIG. 10 indicates a state in which the mold 4 is in contact with the imprint material 7 on the full shot region 83 through step S105 in the specific imprint process. F10d in FIG. 10 indicates a state in which the mold 4 is separated from the cured imprint material 7 on the full shot region 83 through step S106 in the specific imprint process. The specific imprint process is performed while the oxygen concentration between the mold 4 and the substrate 2 is relatively high. Accordingly, oxygen inhibits the curing reaction of the residual imprint material 7′ adhering to the mold 4, and hence the residual imprint material 7′ can be integrated with the imprint material 7 on the substrate 2 in an uncured state. This makes it possible to remove the residual imprint material 7′ adhering to the mold 4.

F10e to F10g in FIG. 10 each indicate an example in which the imprint process is performed for another full shot region 81. F10e in FIG. 10 indicates a state in which a gas supplying operation for the full shot region 81 is controlled through steps S101 to S104. F10f in FIG. 10 indicates a state in which the mold 4 is in contact with the imprint material 7 on the full shot region 81 through step S105. F10g in FIG. 10 indicates a state in which the mold 4 is separated from the cured imprint material 7 on the full shot region 81 through step S106. In the present embodiment, since the residual imprint material 7′ on the mold 4 is removed in the above specific imprint process, it is possible to reduce the occurrence of pattern defects originating from the residual imprint material 7′ in the imprint process for another full shot region 81.

### Third Embodiment

The third embodiment of the present invention will be described. The sequence of the imprint process (including the specific imprint process) for a plurality of shot regions 8 on a substrate 2 in the present embodiment will be described with reference to FIG. 9. FIG. 9 shows the layout of the plurality of shot regions 8 on the substrate 2. As shown in FIG. 9, the plurality of shot regions 8 on the substrate 2 can include a plurality of full shot regions 81 indicated in white, a plurality of partial shot regions 82 indicated in gray, and a full shot region 83 indicated by hatching. The full shot region 83 indicated by hatching is the shot region 8 for which the specific imprint process is performed, as described in the second embodiment. Note that the present embodiment basically follows the second embodiment and can comply with the second embodiment except for the matters described below.

### Example 1

Example 1 describes a case where the full shot region 83 for which the specific imprint process is performed is the shot region 8, of the plurality of shot regions 8 on the substrate 2, for which the imprint process is performed last.

In Example 1, first of all, the imprint process is performed for each of the plurality of full shot regions 81 indicated in white in FIG. 9. In a gas supplying operation in the imprint process for each full shot region 81, as described above, the gas 10a is sufficiently supplied between the mold 4 and the substrate 2 so as to prevent the occurrence of pattern defects due to the mixing of air in the imprint material 7 in the form of air bubbles. The supply amount of the gas 10a is preferably set such that the filling time required to fill the concave portion of the mold 4 (the pattern portion 5) with the imprint material 7 becomes shorter than a desired time, and the number of pattern defects caused by air bubbles becomes smaller than a desired count. Note that the sequence of the imprint process for the plurality of full shot regions 81 can be arbitrarily set.

Upon completion of the imprint process for all the full shot regions 81, the imprint process is performed for the plurality of partial shot regions 82 indicated in gray in FIG. 9. As described above, a gas supplying operation in the imprint process for each partial shot region 82 is controlled such that the supply amount of the gas 10a between the mold 4 and the substrate 2 is smaller than that in a gas supplying operation in the imprint process for each full shot region 81. The supply amount of the gas 10a is controlled such that the curing of the residual imprint material 7′ adhering to the mold 4 (the pattern portion 5) is inhibited by oxygen. For example, in a gas supplying operation in the imprint process for each partial shot region 82, the gas 10a may not be supplied between the mold 4 and the substrate 2. The residual imprint material 7′ adhering to the mold 4 in the imprint process for the partial shot region 82 is in an uncured state and hence is integrated with the imprint material 7 on the substrate 2 in the next imprint process. Accordingly, in the next imprint process, it is possible to reduce the occurrence of pattern defects due to the residual imprint material 7′. Note that the sequence of the imprint process for the plurality of partial shot regions 82 can be arbitrarily set.

Upon completion of the imprint process for all the partial shot regions 82, the specific imprint process is performed for the full shot region 83 indicated by hatching in FIG. 9. As described above, a gas supplying operation in the specific imprint process is controlled such that the supply amount of the gas 10a between the mold 4 and the substrate 2 is smaller than that in a gas supplying operation in the imprint process for each full shot region 81. For example, in a gas supplying operation for a specific shot region, the supply amount of the gas 10a may be the same as that in a gas supplying operation in the imprint process for each partial shot region 82 or the gas 10a may not be supplied between the mold 4 and the substrate 2. Performing this specific imprint process makes it possible to complete the imprint process for the substrate 2 in a state in which the residual imprint material 7′ adhering to the mold 4 due to the imprint process for the partial shot region 82 has been removed and to continue the imprint process for the next substrate.

### Example 2

Example 2 describes a case where after the specific imprint process is performed for the full shot region 83, the imprint process is performed for the remaining full shot regions 81.

In Example 2, first of all, the imprint process is performed for the plurality of partial shot regions 82 indicated in gray in FIG. 9. The imprint process for each partial shot regions 82 is the same as that described in Example 1 and the like, and hence a description thereof will be omitted. Note that the sequence of the imprint process performed for the plurality of partial shot regions 82 can be arbitrarily set.

Upon completion of the imprint process for all the partial shot regions 82, the specific imprint process is performed for the full shot region 83 indicated by hatching in FIG. 9. The imprint process for the full shot region 83 is the same as that described in Example 1 and the like, and hence a description thereof will be omitted. Performing the specific imprint process can remove the residual imprint material 7′ adhering to the mold 4 in the imprint process for the partial shot region 82.

Upon completion of the specific imprint process for the full shot region 83, the imprint process is performed last for each of the plurality of full shot regions 81 indicated in white in FIG. 9. The imprint process for each full shot region 81 is the same as that described in Example 1 and the like, and hence a description thereof will be omitted.

After (immediately after) the imprint process for the full shot region 81, the gas 10a remains between the mold 4 and the substrate 2, that is, the oxygen concentration between the mold 4 and the substrate 2 is relatively low. For this reason, when the imprint process is performed for the partial shot region 82 next to the imprint process for the full shot region 81, it is difficult to secure, between the mold 4 and the substrate 2, an oxygen concentration high enough to inhibit the curing of the residual imprint material 7′ adhering to the mold 4. That is, the residual imprint material 7′ adhering to the mold 4 might be cured. In Example 2, since the imprint process for each partial shot region 82 is performed before the imprint process for all the full shot regions 81, it is possible to suppress the curing of the residual imprint material 7′ adhering to the mold 4 and to reduce the occurrence of pattern defects.

### Embodiment of Article Manufacturing Method

An article manufacturing method according to the embodiment of the present invention is suitable for manufacturing an article, for example, a microdevice such as a semiconductor device or an element having a microstructure. The article manufacturing method according to this embodiment includes a shaping step of shaping a composition on a substrate using the above-described shaping method by a shaping apparatus, a processing step of processing the substrate having the composition shaped in the shaping step, and a manufacturing step of manufacturing an article from the substrate processed in the processing step. An imprint apparatus or a planarization apparatus can be used as the shaping apparatus. The manufacturing method further includes other known steps (oxidation, film formation, deposition, doping, planarization, etching, resist removal, dicing, bonding, packaging, and the like). The article manufacturing method of this embodiment is more advantageous than the conventional methods in at least one of the performance, quality, productivity, and production cost of the article.

The pattern of a cured product shaped using the above-described shaping apparatus is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile and nonvolatile semiconductor memories such as a DRAM, an SRAM, a flash memory, and an MRAM and semiconductor elements such as an LSI, a CCD, an image sensor, and an FPGA. An example of the mold is a mold for imprint.

The pattern of the cured product is directly used as the constituent member of at least some of the above-described articles or used temporarily as a resist mask. After etching or ion implantation is performed in the substrate processing step, the resist mask is removed.

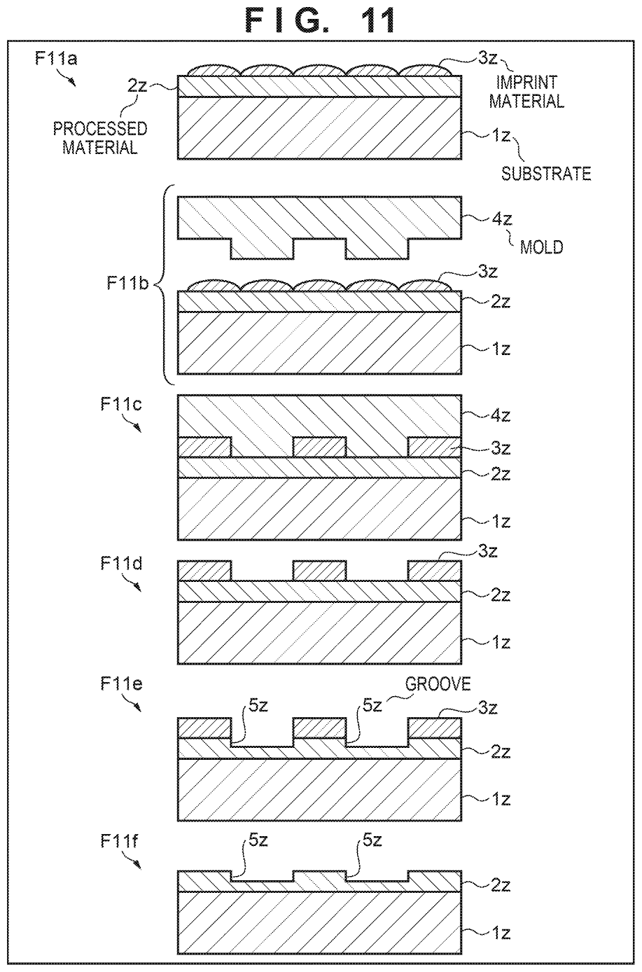

A practical manufacturing method for an article in a case where an imprint apparatus is used as the shaping apparatus will be described next. As indicated by F11a in FIG. 11, a substrate 1z such as a silicon wafer with a processed material 2z such as an insulator formed on the surface is prepared. Next, an imprint material 3z is applied to the surface of the processed material 2z by an inkjet method or the like. A state in which the imprint material 3z is applied as a plurality of droplets onto the substrate is shown here.

As indicated by F11b in FIG. 11, a side of a mold 4z for imprint with a concave-convex pattern is directed to face the imprint material 3z on the substrate. As indicated by F11c in FIG. 11, the mold 4z and the substrate 1z to which the imprint material 3z has been applied are brought into contact with each other, and a pressure is applied. The gap between the mold 4z and the processed material 2z is filled with the imprint material 3z. In this state, when the imprint material 3z is irradiated with light as curing energy via the mold 4z, the imprint material 3z is cured.

As indicated by F11d in FIG. 11, after the imprint material 3z is cured, the mold 4z is separated from the substrate 1z, and the pattern of the cured product of the imprint material 3z is formed on the substrate 1z. In the pattern of the cured product, the concave portion of the mold corresponds to the convex portion of the cured product, and the convex portion of the mold corresponds to the concave portion of the cured product. That is, the concave-convex pattern of the mold 4z is transferred to the imprint material 3z.

As indicated by F11e in FIG. 11, when etching is performed using the pattern of the cured product as an etching resistant mask, a portion of the surface of the processed material 2z where the cured product does not exist or remains thin is removed to form a groove 5z. As indicated by F11f in FIG. 11, when the pattern of the cured product is removed, an article with the grooves 5z formed in the surface of the processed material 2z can be obtained. Here, the pattern of the cured product is removed. However, instead of removing the pattern of the cured product after the process, it may be used as, for example, an interlayer dielectric film included in a semiconductor element or the like, that is, a constituent member of an article.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

1. A shaping method of performing, for each of a plurality of regions on a substrate, a process of curing a composition on the substrate while keeping a mold in contact with the composition and shaping the composition on the substrate by separating the mold from the cured composition, wherein
the plurality of regions include a first region that does not include an outer edge portion of the substrate and a second region that includes the outer edge portion,
the composition on the substrate has a property of being inhibited from being cured by oxygen,
the process includes controlling a gas supplying operation of supplying a gas lower in oxygen concentration than air between the mold and the substrate before bringing the mold into contact with the composition on the substrate, and
the supply amount of the gas in the gas supplying operation in the process for the second region is smaller than the supply amount of the gas in the gas supplying operation in the process for the first region.

2. The shaping method according to claim 1, wherein in the gas supplying operation in the process for the second region, the supply amount of the gas is controlled such that an oxygen concentration around the second region at a time of curing the composition on the second region becomes higher than an oxygen concentration around the first region at a time of curing the composition on the first region.

3. The shaping method according to claim 1, wherein in the gas supplying operation in the process for the second region, the supply amount of the gas is controlled such that the composition adhering to the mold through the process for the second region is inhibited from being cured and remains in an uncured state.

4. The shaping method according to claim 1, wherein in the gas supplying operation in the process for the second region, the gas is not supplied between the mold and the substrate.

5. The shaping method according to claim 1, wherein in the process for the second region, a time from bringing the mold into contact with the composition on the substrate to starting to cure the composition is longer than in the process for the first region.

6. The shaping method according to claim 1, wherein
the plurality of regions further include a third region that does not include the outer edge portion,
the process for the third region is performed subsequent to the process for the second region, and
the supply amount of the gas in the gas supplying operation in the process for the third region is smaller than in the gas supplying operation in the process for the first region.

7. The shaping method according to claim 6, wherein
the supply amount of the gas is controlled in the gas supplying operation in the process for the second region such that the composition adhering to the mold through the process for the second region is inhibited from being cured by oxygen around the second region and remains in an uncured state, and
the supply amount of the gas is controlled in the gas supplying operation in the process for the third region such that the composition adhering to the mold through the process for the second region is inhibited from being cured by oxygen around the third region and integrated with the composition on the third region in an uncured state.

8. The shaping method according to claim 6, wherein the third region is a region of the plurality of regions for which the process is performed last.

9. The shaping method according to claim 6, wherein the process for the first region is performed after the process for the third region.

10. A shaping method of performing, for each of a plurality of regions on a substrate, a process of curing a composition on the substrate while keeping a mold in contact with the composition and shaping the composition on the substrate by separating the mold from the cured composition, wherein
the plurality of regions include a first region that does not include an outer edge portion of the substrate and a second region that includes the outer edge portion,
the composition on the substrate has a property of being inhibited from being cured by oxygen, and
an oxygen concentration around the second region at the time of curing the composition on the second region is higher than an oxygen concentration around the first region at the time of curing the composition on the first region.

11. An article manufacturing method comprising:
shaping a composition on a substrate by using a shaping method defined in claim 1;
processing the substrate having the shaped composition; and
manufacturing an article from the processed substrate.

12. A shaping apparatus which performs, for each of a plurality of regions on a substrate, a process of curing a composition on the substrate while keeping a mold in contact with the composition and shapes the composition on the substrate by separating the mold from the cured composition, comprising:
a supplier configured to supply, between the mold and the substrate, a gas lower in oxygen concentration than air; and
a controller configured to control the process,
wherein the plurality of regions include a first region that does not include an outer edge portion of the substrate and a second region that includes the outer edge portion of the substrate,
wherein the composition on the substrate has a property of being inhibited from being cured by oxygen,
wherein a gas supplying operation of supplying the gas by the supplier is controlled in the process before the mold is brought into contact with the composition on the substrate, and
wherein the controller is configured to control the gas supplying operation in the process for the second region such that the supply amount of the gas becomes smaller than in the gas supplying operation in the process for the first region.

13. A shaping apparatus which performs, for each of a plurality of regions on a substrate, a process of curing a composition on the substrate while keeping a mold in contact with the composition and shapes the composition on the substrate by separating the mold from the cured composition, comprising:
a supplier configured to supply, between the mold and the substrate, a gas lower in oxygen concentration than air; and
a controller configured to control the process,
wherein the plurality of regions include a first region that does not include an outer edge portion of the substrate and a second region that includes the outer edge portion,
wherein the composition on the substrate has a property of being inhibited from being cured by oxygen, and
wherein the controller is configured to control the supplier such that an oxygen concentration around the second region at the time of curing the composition on the second region becomes higher than an oxygen concentration around the first region at the time of curing the composition on the first region.
